(19) United States
(12) Patent Application Publication
(10) Pub. No.: US 2021/0089740 A1
(43) Pub. Date: Mar. 25, 2021

(54) DISPLAY PANEL AND DISPLAY DEVICE

(71) Applicant: EverDisplay Optronics (Shanghai) Limited, Shanghai (CN)

(72) Inventors: Zhao WANG, Shanghai (CN); Zhijiang HE, Shanghai (CN); Hsin Chih LIN, Shanghai (CN); Jia WEI, Shanghai (CN)

(73) Assignee: EverDisplay Optronics (Shanghai) Limited, Shanghai (CN)

(21) Appl. No.: 16/854,061

(22) Filed: Apr. 21, 2020

(30) Foreign Application Priority Data
Sep. 24, 2019 (CN) 201910904245.X

(51) Int. Cl. G06K 9/00; H01L 27/32; H01L 51/52; G06K 9/20

(52) U.S. Cl. CPC G06K 9/0004; H01L 27/3244; H01L 27/323; G02B 5/3083; H01L 51/5281; G06K 9/209; H01L 27/3234

(57) ABSTRACT

The disclosure discloses a display panel and a display device, comprising: an OLED substrate; an optical fingerprint sensor; a first quarter-wave plate; a first linear polarizer provided on one side, away from the OLED substrate, of the first quarter-wave plate; a second quarter-wave plate provided on one side, facing to the optical fingerprint sensor, of the OLED substrate; a second linear polarizer provided on one side, facing away from the OLED substrate, of the second quarter-wave plate and positioned between the second quarter-wave plate and the optical fingerprint sensor.

### CROSS REFERENCE TO RELATED APPLICATIONS

10001 The present application is based upon and claims the priority of Chinese Patent Application No. 201910904245.X, tided “DISPLAY PANEL AND DISPLAY DEVICE”, filed on Sep. 24, 2019. The entire content of this Chinese patent application is incorporated herein by reference.

### FIELD

The disclosure relates to the technology in the field of OLED display, in particular to a display panel and a display device.

### BACKGROUND

Organic Light Emitting Diode (OLED) display devices have many advantages, such as self-emission, low driving voltage, high efficiency, short response time, high definition and contrast, near 180° viewing angle, wide temperature range, flexible display and large-area full-color display, which are recognized by the industry as the most promising display devices.

OLED display devices can be classified into passive matrix OLED (PMOLED) and active matrix OLED (AMOLED) according to driving modes, namely direct addressing and thin film transistor (TFT) matrix addressing. The AMOLED has pixels provided in an array mode, belongs to an active display type, has high luminous efficiency and is generally used as a high-definition large-size display device.

An AMOLED is a current driving device that emits light when a current flows through the organic light emitting diode, and the light emission brightness is determined by the current flowing through the organic light emitting diode itself. Most existing integrated circuits (ICs) only transmit voltage signals, so the pixel driving circuit of AMOLED needs to complete the task of converting voltage signals into current signals. A conventional AMOLED pixel driving circuit is usually 2T1C, that is, a structure in which two thin film transistors are added with a capacitor to convert a voltage into a current.

### SUMMARY

According to an embodiment of the present disclosure, provided is a display panel comprising:

an OLED substrate;

an optical fingerprint sensor provided on one side of the OLED substrate and configured to receive light emitted from the OLED substrate facing away from the optical fingerprint sensor and reflected by a detected object;

a first quarter-wave plate provided on one side, away from the optical fingerprint sensor, of the OLED substrate;

a first linear polarizer provided on one side, away from the OLED substrate, of the first quarter-wave plate;

a second quarter-wave plate provided on one side, facing to the optical fingerprint sensor, of the OLED substrate; and

a second linear polarizer provided on the side, facing away from the OLED substrate, of the second quarter-wave plate and positioned between the second quarter-wave plate and the optical fingerprint sensor.

According to an embodiment, the light path of the light comprises an emergent light path and an incident light path;

The light sequentially passes through the first quarter-wave plate and the first linear polarizer along the emergent light path and then exits out of the display panel:

The light sequentially passes through the first linear polarizer, the first quarter-wave plate, the OLED substrate, the second quarter-wave plate and the second linear polarizer along the incident light path and is incident to the optical fingerprint sensor.

According to an embodiment, the polarization direction of the first linear polarizer and the polarization direction of the second linear polarizer are parallel.

According to an embodiment, the side surface, facing to the OLED substrate, of the first quarter-wave plate is provided with an adhesive layer.

According to an embodiment, one side surface, facing to the OLED substrate, of the second quarter-wave plate is provided with an adhesive layer.

According to an embodiment, the side of the first linear polarizer facing away from the OLED substrate is provided with a touch cover plate.

According to an embodiment, the OLED substrate has a fingerprint light emitting area, and the optical fingerprint sensor is located within the fingerprint light emitting area.

According to an embodiment, a portion of the area within the fingerprint light emitting area of the OLED substrate emits white light in response to a touch signal generated by the touch cover plate.

According to an embodiment, the second quarter-wave plate and the second linear polarizer both cover the fingerprint light emitting area.

According to an embodiment, the first quarter-wave plate and the first linear polarizer both cover the OLED substrate.

According to an embodiment of the present disclosure, there is provided a display device comprising the above display panel.

Other features and advantages of the disclosure, as well as the structure and operation of various embodiments of the disclosure, will be described in detail hereinafter with reference to the accompanying drawings. It should be noted that the disclosure is not limited to the specific embodiments described herein. These examples are given herein for illustrative purposes only.

### BRIEF DESCRIPTION OF THE DRAWINGS

Other features, objects, and advantages of the present disclosure will become apparent from the following detailed description of non-limiting embodiments, which proceeds with reference to the accompanying drawings.

FIG. 1 is a schematic view showing a structure of a display panel according to an embodiment of the present disclosure;

FIG. 2 is a schematic view showing a structure of a display panel according to an embodiment of the present disclosure;

FIG. 3 is a schematic diagram of light propagation in an embodiment of the present disclosure;

FIG. 4 is a schematic view showing a structure of a display panel according to another embodiment of the present disclosure.

The features and advantages of the present disclosure will become more apparent from the following detailed description taken in conjunction with the accompanying drawings. Throughout the drawings, the same reference numerals identify corresponding elements. In the drawings, like reference numerals generally indicate identical, functionally similar, and/or structurally similar elements.

### DETAILED DESCRIPTION

The technical solutions in the embodiments of the present disclosure are clearly and completely described in the following with reference to the accompanying drawings in the embodiments of the present disclosure. It is obvious that the described embodiments are only a part of the embodiments of the present disclosure, and not all of the embodiments. All other embodiments obtained by those of ordinary skill in the art based on the embodiments of the present disclosure without creative efforts are within the scope of the present disclosure.

As used herein, “first”. “second”, and similar terms do not denote any order, quantity, or importance, but rather are used solely to distinguish one from another. The word “comprising” or “comprises”, and the like, means that an element or article that precedes the word is inclusive of the element or article listed after the word and equivalents thereof, but does not exclude other elements or articles. The terms “connected” or “connected to”, and the like, are not limited to physical or mechanical connections, but may include electrical connections, whether direct or indirect. The terms “upper”, “lower”, “left”, “right”, and the like are used merely to indicate a relative positional relationship that may change accordingly when the absolute position of the object described changes.

It should be noted that embodiments of the disclosure and features of the embodiments may be combined with one another without conflict.

The present disclosure is further illustrated, but not limited, by the accompanying drawings and specific examples.

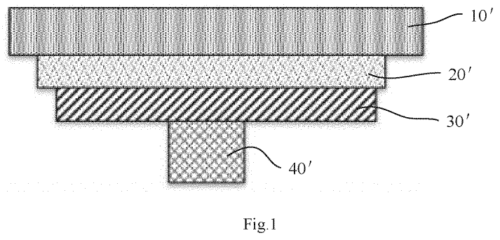

In OLED display devices, fingerprint information of a user may be recognized by providing a fingerprint recognition sensor below a screen. FIG. 1 is a schematic view showing a structure of a display panel according to an embodiment of the present disclosure. Referring to FIG. 1, a touch cover plate 10′ is provided on one side of an OLED substrate 30′, a polarizing layer 20′ is provided between the OLED substrate 30′ and the touch cover plate 10′ and a fingerprint sensor 40′ is provided on the other side of the OLED substrate. In fingerprint detection, light emitted by the OLED substrate 30′ passes through the polarizing layer 20′ and the touch cover plate 10′, then is reflected by a detected object (finger) and then passes through the touch cover plate 10′, the polarizing layer 20′, and the OLED substrate 30′ and is received by the fingerprint sensor 40′. However, since there is a light leakage from the OLED substrate 30, that is, a portion of the light emitted from the OLED substrate 30′ toward the fingerprint sensor 40′, the light leakage is received by the fingerprint sensor 40′ together with the light reflected from the object to be detected (finger) through the touch cover plate 10′, the polarizing layer 20′, and the light emitted from the OLED substrate 30′ into the fingerprint sensor 40′, thereby reducing the recognition accuracy of the fingerprint sensor 40′. When the light leakage ratio is too large, even the fingerprint sensor 40′ cannot perform effective recognition.

According to an embodiment of the present disclosure, a display panel is provided. The display panel includes: an OLED substrate; an optical fingerprint sensor provided on one side of the OLED substrate and configured to receive light emitted from the OLED substrate facing away from the optical fingerprint sensor and reflected by a detected object; a first quarter-wave plate provided on one side, away from the optical fingerprint sensor, of the OLED substrate; a first linear polarizer provided on one side, away from the OLED substrate, of the first quarter-wave plate; a second quarter-wave plate provided on one side, facing to the optical fingerprint sensor, of the OLED substrate; and a second linear polarizer provided on the side, facing away from the OLED substrate, of the second quarter-wave plate and positioned between the second quarter-wave plate and the optical fingerprint sensor. According to the display panel, the quarter-wave plate and the linear polarizer are provided between the optical fingerprint sensor and the OLED substrate, and the quarter-wave plate and the linear polarizer are provided between the OLED substrate and the touch cover plate, so that light leakage from the OLED substrate is reduced, the proportion of reflected light to incident light of the whole optical fingerprint sensor is improved, and the sensitivity of the optical fingerprint sensor is improved.

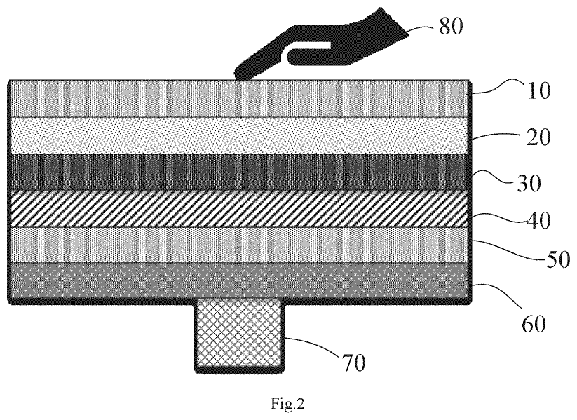

FIG. 2 is a schematic view showing a structure of a display panel according to an embodiment of the present disclosure. The display panel shown in FIG. 2 comprises an OLED substrate 40 and an optical fingerprint sensor 70 provided on one side of the OLED substrate 40. i.e. the optical fingerprint sensor 70 is provided on the back side of the OLED substrate 40. The display panel further includes a controller (not shown) coupled to the OLED substrate 40 and the optical fingerprint sensor 70 for controlling the enabling of the optical fingerprint sensor 70. The OLED substrate 40 includes, but is not limited to: an cathode, an electron injection layer, an electron transport layer, an organic light emitting layer, an hole transport layer, an hole injection layer and an anode, wherein the cathode and the anode are connected through a power supply, and the power supply can be implemented as a current source or a voltage source; as the light emitting side of the OLED substrate 40, the cathode should be made of a thin metal or a transparent conductive oxide should be used as the cathode. The OLED substrate 40 emits light through the cathode, but there is a light leakage 93 on the anode side (the side facing to the optical fingerprint sensor 70) which is received by the optical fingerprint sensor 70. The optical fingerprint sensor 70 is an optical sensor for detecting reflected light 92, may be a photodiode or photoconductor, and may further provide an additional element such as a circuit element for measuring a change in resistance in the photoconductor or a condensing element for focusing light onto the photodiode. The optical fingerprint sensor 70 is capable of sensing the reflected light 92 output from the pixels of the OLED substrate 40 and reflected by the subject 80 (finger), and is capable of recognizing the outline (fingerprint ridge or valley) of the fingerprint of the finger according to the reflected light 92.

Referring again to FIG. 2, a first quarter-wave plate 30 is provided on the light emitting side of the OLED substrate 40 (the side facing away from the optical fingerprint sensor 70), a first linear polarizer 20 is provided on the side of the first quarter-wave plate 30 facing away from the OLED substrate 40, and a touch cover plate 10 is provided on the side of the first linear polarizer 20 facing away from the first quarter-wave plate 30, i.e. the light emitting side of the OLED substrate 40 is sequentially provided with the first quarter-wave plate 30. First linear polarizer 20 and touch cover plate 10. A second quarter-wave plate 50 and a second linear polarizer 60 are provided on the backlight side (the side facing to the optical fingerprint sensor 70) of the OLED substrate 40, i.e. the second quarter-wave plate 50 and the second linear polarizer 60 are sequentially provided between the OLED substrate 40 and the optical fingerprint sensor 70. The quarter-wave plate is a birefringent single crystal wave plate with a certain thickness; when light is transmitted through the wave plate from normal incidence, the phase between ordinary light (o-light) and extraordinary light (e-light) is equal to π/2 or an odd multiple thereof, and such wafers are referred to as quarter-wave plates or quarter-wave plates. When linearly polarized light vertically enters the quarter-wave plate, the polarization of the light and the optical axis surface (vertical natural split surface) of the wave plate form an angle θ, and the light is elliptically polarized after being emitted. The polarization directions of the first linear polarizer 20 and the second linear polarizer 60 are parallel to each other. The optical fingerprint sensor 70 is capable of identifying the contour (fingerprint ridge or valley) of the fingerprint of the finger from the reflected light 92 of the object 80 (finger).

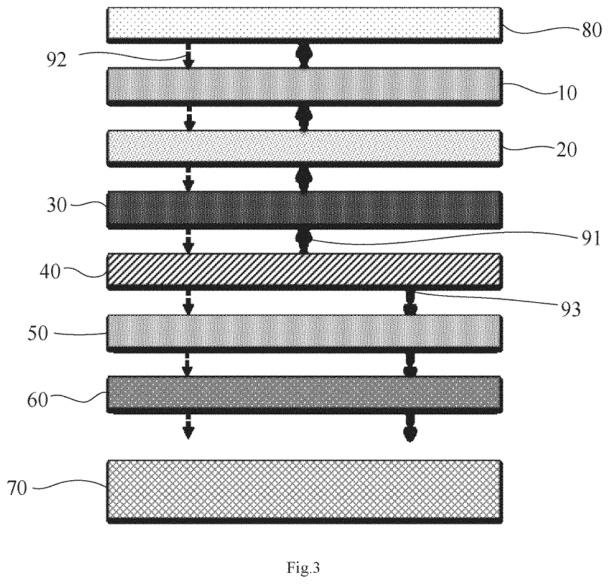

FIG. 3 is a schematic diagram of light propagation in an embodiment of the present disclosure. The light emitting side of the OLED substrate 40 emits emission light 91, and the backlight side of the OLE substrate leaks light 93. The emergent light 91 emitted from the OLED substrate 40 propagates along an emergent light path, that is, the emergent light 91 passes through the first quarter-wave plate 30, the first linear polarizer 20 and the touch cover plate 10 to reach the surface of the object 80 to be measured, wherein the emergent light 91 becomes linearly polarized light after passing through the first linear polarizer 20. The emergent light 91 forms reflected light 92 after being reflected on the surface of the object 80, the reflected light 92 propagates along a reflected light path, and the reflected light 92 sequentially passes through the first linear polarizer 20, the first quarter-wave plate 30, the OLED substrate 40, the second quarter-wave plate 50 and the second linear polarizer 60 along the reflected light path, wherein the reflected light 92 becomes elliptically polarized light after passing through the first quarter-wave plate 30; the reflected light 92 becomes linearly polarized after passing through the second quarter-wave plate 50 so that the reflected light 92 can pass through the second linearly polarized plate 60. The OLED substrate 40 leaks light 93 which passes through the second quarter-wave plate 50 and the second linear polarizer 60 in turn, and the light leakage 93 becomes linearly polarized after passing through the second linear polarizer 60, thereby reducing the amount of light by 50%. The optical fingerprint sensor 70 can recognize the contour (fingerprint ridge or valley) of the fingerprint of the finger according to the reflected light 92 of the object 80 (finger) to be measured, and the sensitivity of the optical fingerprint sensor 70 is improved and the recognition accuracy is further improved due to the increased proportion of the emitted light in the light rays injected into the optical fingerprint sensor 70.

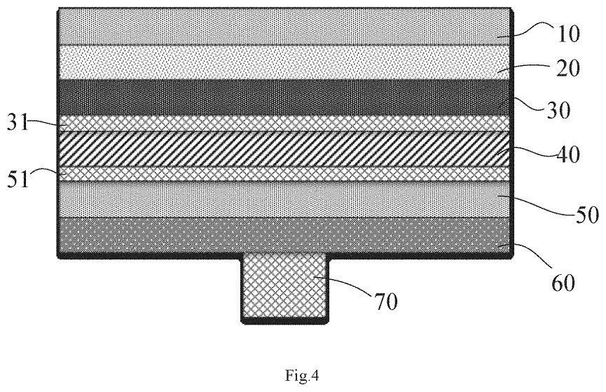

FIG. 4 is a schematic view showing a structure of a display panel according to another embodiment of the present disclosure. A first quarter-wave plate 30 is provided on the light emitting side (the side facing away from the optical fingerprint sensor 70) of the OLED substrate 40, a first linear polarizer 20 is provided on the side of the first quarter-wave plate 30 facing away from the OLED substrate 40, and a touch cover plate 10 is provided on the side of the first linear polarizer 20 facing away from the first quarter-wave plate 30, i.e. the light emitting side of the OLED substrate 40 is sequentially provided with the first quarter-wave plate 30, the first linear polarizer 20 and the touch cover plate 10. A second quarter-wave plate 50 and a second linear polarizer 60 are provided on the backlight side (the side facing to the optical fingerprint sensor 70) of the OLED substrate 40, i.e. the second quarter-wave plate 50 and the second linear polarizer 60 are sequentially provided between the OLED substrate 40 and the optical fingerprint sensor 70. Unlike the display panel shown in FIG. 2; a first glue layer 31 is provided between the first quarter-wave plate 30 and the OLED substrate 40, and a second glue layer 51 is provided between the second quarter-wave plate 50 and the OLED substrate 40. The first quarter-wave plate 30 can be directly adhered to the surface of the light emitting side of the OLED substrate 40 through the first adhesive layer 31; the second quarter-wave plate 50 can be directly adhered to the surface of the backlight side of the OLED substrate 40 through the second glue layer 51.

In some embodiments, OLED substrate 40 has a fingerprint light emitting area and an optical fingerprint sensor 70 is located within the fingerprint light emitting area. The controller causes a portion of the area within the fingerprint light emitting area of the OLED substrate 40 to emit white light in response to a touch signal generated by the touch cover plate 10. The second quarter-wave plate 50 and the second linear polarizer 60 both cover the fingerprint light emitting area. Both the first quarter-wave plate 30 and the first linear polarizer 20 cover the OLED substrate 40.

According to an embodiment of the present disclosure, there is provided a display device comprising the above display panel.

In summary, according to the display panel and the display device, the quarter-wave plate and the linear polarizer are provided between the optical fingerprint sensor and the OLED substrate, and the quarter-wave plate and the linear polarizer are provided between the OLED substrate and the touch cover plate, so that light leakage from the OLED substrate is reduced, the proportion of reflected light to incident light of the whole optical fingerprint sensor is improved, and the sensitivity of the optical fingerprint sensor is improved.

The technical scheme has the beneficial effects that: according to the display panel and the display device, the quarter-wave plate and the linear polarizer are provided between the optical fingerprint sensor and the OLED substrate, and the quarter-wave plate and the linear polarizer are provided between the OLED substrate and the touch cover plate, so that light leakage from the OLED substrate is reduced, the proportion of reflected light to incident light of the whole optical fingerprint sensor is improved, and the sensitivity of the optical fingerprint sensor is improved.

The foregoing is a further detailed description of the disclosure, taken in conjunction with specific preferred embodiments, and is not to be construed as limiting the disclosure to those specific embodiments. It will be apparent to those skilled in the art that various modifications and variations can be made in the present disclosure without departing from the spirit or scope of the disclosure.

What is claimed is:

1. A display panel, comprising:
an OLED substrate;
an optical fingerprint sensor provided on one side of the OLED substrate and configured to receive light emitted from the OLED substrate facing away from the optical fingerprint sensor and reflected by a detected object;
a first quarter-wave plate provided on one side, away from the optical fingerprint sensor, of the OLED substrate;
a first linear polarizer provided on one side, away from the OLED substrate, of the first quarter-wave plate;
a second quarter-wave plate provided on one side, facing to the optical fingerprint sensor, of the OLED substrate; and
a second linear polarizer provided on one side, facing away from the OLED substrate, of the second quarter-wave plate and positioned between the second quarter-wave plate and the optical fingerprint sensor.

2. The display panel according to claim 1, wherein, a light path of the light comprises an emergent light path and an incident light path;
the light sequentially passes through the first quarter-wave plate and the first linear polarizer along the emergent light path and then is emitted out of the display panel; and
the light sequentially passes through the first linear polarizer, the first quarter-wave plate, the OLED substrate, the second quarter-wave plate and the second linear polarizer along the incident light path and is incident to the optical fingerprint sensor.

3. The display panel according to claim 1, wherein, a polarization direction of the first linear polarizer and a polarization direction of the second linear polarizer are parallel.

4. The display panel according to claim 1, wherein, one side surface, facing to the OLED substrate, of the first quarter-wave plate is provided with an adhesive layer.

5. The display panel according to claim 1, wherein, one side surface, facing to the OLED substrate, of the second quarter-wave plate is provided with an adhesive layer.

6. The display panel according to claim 1, wherein, a touch cover plate is provided on one side, facing away from the OLED substrate, of the first linear polarizer.

7. The display panel according to claim 6, wherein, the OLED substrate has a fingerprint light emitting area and the optical fingerprint sensor is located within the fingerprint light emitting area.

8. The display panel according to claim 7, wherein, in response to a touch signal generated by the touch cover plate, a portion of the area within the fingerprint light emitting area of the OLED substrate emits white light.

9. The display panel according to claim 7, wherein, the second quarter-wave plate and the second linear polarizer both cover the fingerprint light emitting area.

10. The display panel according to claim 1, wherein, the first quarter-wave plate and the first linear polarizer both cover the OLED substrate.

11. A display device, comprising a display panel, wherein the display panel comprises:
an OLED substrate;
an optical fingerprint sensor provided on one side of the OLED substrate and configured to receive light emitted from the OLED substrate facing away from the optical fingerprint sensor and reflected by a detected object;
a first quarter-wave plate provided on one side, away from the optical fingerprint sensor, of the OLED substrate;
a first linear polarizer provided on one side, away from the OLED substrate, of the first quarter-wave plate;
a second quarter-wave plate provided on one side, facing to the optical fingerprint sensor, of the OLED substrate; and
a second linear polarizer provided on one side, facing away from the OLED substrate, of the second quarter-wave plate and positioned between the second quarter-wave plate and the optical fingerprint sensor.

12. The display device according to claim 11, wherein, a light path of the light comprises an emergent light path and an incident light path;
the light sequentially passes through the first quarter-wave plate and the first linear polarizer along the emergent light path and then is emitted out of the display panel; and
the light sequentially passes through the first linear polarizer, the first quarter-wave plate, the OLED substrate, the second quarter-wave plate and the second linear polarizer along the incident light path and is incident to the optical fingerprint sensor.

13. The display device according to claim 11, wherein, a polarization direction of the first linear polarizer and a polarization direction of the second linear polarizer are parallel.

14. The display device according to claim 11, wherein, one side surface, facing to the OLED substrate, of the first quarter-wave plate is provided with an adhesive layer.

15. The display device according to claim 11, wherein, one side surface, facing to the OLED substrate, of the second quarter-wave plate is provided with an adhesive layer.

16. The display device according to claim 11, wherein, a touch cover plate is provided on one side, facing away from the OLED substrate, of the first linear polarizer.

17. The display device according to claim 16, wherein, the OLED substrate has a fingerprint light emitting area and the optical fingerprint sensor is located within the fingerprint light emitting area.

18. The display device according to claim 17, wherein, in response to a touch signal generated by the touch cover plate, a portion of the area within the fingerprint light emitting area of the OLED substrate emits white light.

19. The display device according to claim 17, wherein, the second quarter-wave plate and the second linear polarizer both cover the fingerprint light emitting area.

20. The display device according to claim 11, wherein, the first quarter-wave plate and the first linear polarizer both cover the OLED substrate.
